(19) United States
(12) Patent Application Publication
(10) Pub. No.: US 2026/0107509 A1
(43) Pub. Date: Apr. 16, 2026

(54) SEMICONDUCTOR DEVICE, AND METHOD FOR FABRICATING THE SAME

(71) Applicant: Taiwan Semiconductor Manufacturing Company, Ltd., Hsinchu (TW)

(72) Inventors: Ta-Chun LIN, Hsinchu (TW); Jhon Jhy LIAW, Hsinchu (TW)

(73) Assignee: Taiwan Semiconductor Manufacturing Company, Ltd., Hsinchu (TW)

(21) Appl. No.: 18/911,824

(22) Filed: Oct. 10, 2024

(51) Int. Cl. H01L 29/423; H01L 29/06; H01L 29/417; H01L 29/66; H01L 29/775; H01L 29/786

(52) U.S. Cl. CPC H10D 30/6735; H10D 30/014; H10D 30/43; H10D 30/6729; H10D 30/6757; H10D 62/121; H10D 64/017; H10D 64/018

(57) ABSTRACT

A method is provided for fabricating a semiconductor device. A fin feature is provided over a semiconductor substrate, with a dummy gate feature being disposed over the fin feature. The fin feature includes sacrificial layers and semiconductor layers alternately stacked together. The sacrificial layers are etched into recessed sacrificial layers. Hydrogen or nitrogen treatment is performed on side surfaces of the recessed sacrificial layers, followed by forming inner spacers and source-drain features. The dummy gate feature is removed, and the recessed sacrificial layers are etched. During the etching of the recessed sacrificial layers, the semiconductor layers are formed to have indentations at positions corresponding to the side surfaces of the recessed sacrificial layers. Then, a gate dielectric and a gate electrode are formed on the semiconductor layers of the fin feature.

### BACKGROUND

The semiconductor integrated circuit (IC) industry has over the past decades experienced tremendous advancements and is still experiencing vigorous development. With the dramatic advances in IC design, new generations of ICs have smaller and more complex structures. Gate-all-around (GAA) devices (e.g., nanosheet transistors, nanorod transistors, nanowire transistors, etc.) have been developed to have a stacked nanosheet structure surrounded by a gate structure, so as to increase the effective channel width in a transistor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an X-cut view of a semiconductor circuit structure in accordance with a first embodiment.

FIG. 2 is a Y-cut view of a semiconductor circuit structure in accordance with the first embodiment.

FIG. 3 is a schematic diagram illustrating a profile of a semiconductor device fabricated in accordance with the first embodiment.

FIG. 4 is an X-cut view of a semiconductor circuit structure in accordance with a second embodiment.

FIG. 5 is a fragmentary enlarged X-cut view of a semiconductor device in accordance with the second embodiment.

FIG. 6 is a schematic diagram illustrating a profile of a semiconductor device fabricated in accordance with the second embodiment.

FIG. 7 is a fragmentary enlarged view of the semiconductor device in accordance with the second embodiment, where a gate dielectric segment of the semiconductor device is thicker at corner portions.

FIG. 8 is a flow chart illustrating a method for fabricating a semiconductor device in accordance with the second embodiment.

FIGS. 9 to 16 are sectional views illustrating steps of the method in accordance with the second embodiment.

FIG. 17 is a sectional view illustrating a variation related to the method in accordance with the second embodiment.

FIG. 18 is an X-cut view illustrating a semiconductor circuit structure in accordance with a first variation of the second embodiment.

FIG. 19 is an X-cut view illustrating a semiconductor circuit structure in accordance with a second variation of the second embodiment.

FIG. 20 is an X-cut view illustrating a semiconductor circuit structure in accordance with a third variation of the second embodiment.

FIG. 21 is an X-cut view illustrating a semiconductor circuit structure in accordance with a fourth variation of the second embodiment.

FIG. 22 is an X-cut view illustrating a semiconductor circuit structure in accordance with a fifth variation of the second embodiment.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

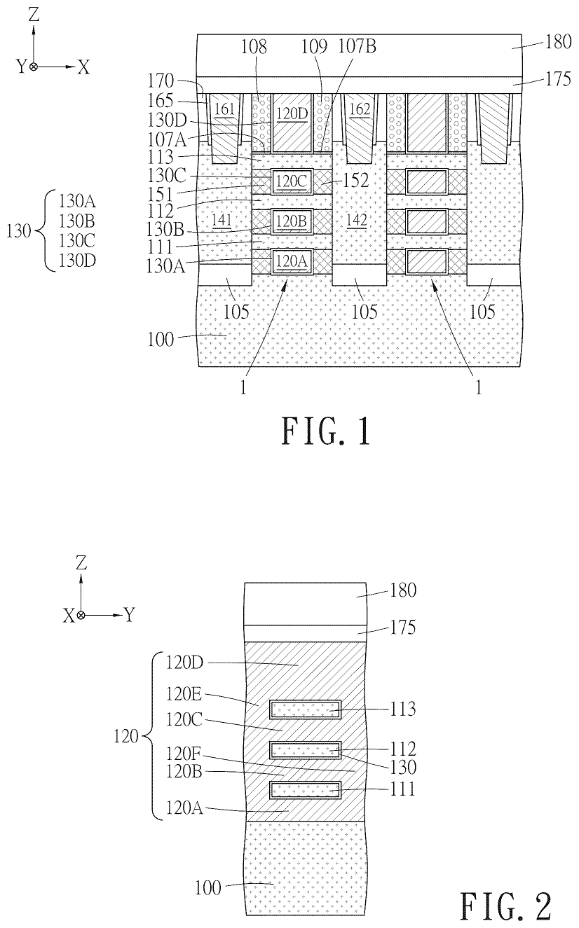

FIG. 1 illustrates an X-cut view of a semiconductor circuit structure in accordance with a first embodiment. In the illustrative embodiment, the semiconductor circuit structure is exemplified to include a plurality of semiconductor devices 1, each of which is a nanosheet FET, but this disclosure is not limited in this respect. In other embodiments, the semiconductor circuit structure may include other types of circuit components, such as nanowire FETs, forksheet FETs, complementary FETs (CFETs), other suitable components, or any combination thereof. The semiconductor circuit structure is formed over a semiconductor substrate 100.

The semiconductor substrate 100 may be a bulk semiconductor substrate or a semiconductor-on-insulator (SOI) substrate, which may be doped (e.g., with a p-type or an n-type dopant) or undoped. In some embodiments, an SOI substrate includes a layer of a semiconductor material formed on an insulator layer. The insulator layer may be a buried oxide (BOX) layer, a silicon oxide layer or any other suitable layer. The insulator layer may be provided on a suitable substrate, such as silicon, glass or the like. The semiconductor substrate 100 may be made of a suitable semiconductor material, such as silicon or the like. In some embodiments, the semiconductor substrate 100 is a silicon wafer; and in other embodiments, the semiconductor substrate 100 is made of a compound semiconductor such as silicon carbide, gallium arsenide, indium arsenide, indium phosphide or other suitable materials. In still other embodiments, the semiconductor substrate 100 is made of an alloy semiconductor such as GaAsP, AlInAs, AlGaAs, GaInAs, GaInP, GaInAsP or other suitable materials.

In some embodiments, the semiconductor substrate 100 includes various p-type doped regions and/or n-type doped regions, such as p-type wells, n-type wells, p-type source/drain features and/or n-type source/drain features, formed by a suitable process such as ion implantation, thermal diffusion, a combination thereof, or the like. In some embodiments, the semiconductor substrate 100 may include other functional elements such as resistors, capacitors, diodes, transistors, and/or the like. The transistors are, for example, field effect transistors (FETs), such as planar FETs and/or 3D FETs (e.g., FinFETs, GAAFETs). The semiconductor substrate 100 may include lateral isolation features (e.g., shallow trench isolation (STI)) configured to separate various functional elements formed on and/or in the semiconductor substrate 100.

In the illustrative embodiment, since the semiconductor devices 1 have similar structures, the following descriptions will only focus on one of the semiconductor devices 1 for the sake of brevity.

Further referring to FIG. 2, FIG. 2 illustrates a Y-cut view of the semiconductor device 1 taken from a central portion of a gate electrode 120 in an X-axis direction. The semiconductor device 1 includes a plurality of channel features 111, 112, 113 disposed over the semiconductor substrate 100, the gate electrode 120 surrounding each of the channel features 111, 112, 113, a gate dielectric 130 disposed between the gate electrode 120 and each of the channel features 111, 112, 113, a first source-drain feature 141 connected to a first end of each of the channel features 111, 112, 113, and a second source-drain feature 142 connected to a second end of each of the channel features 111, 112, 113, where the second ends of the channel features 111, 112, 113 are away from and opposite to the first ends of the channel features 111, 112, 113, respectively. It is noted that the number of channel features is not a limitation of the disclosure, and there may be one, two, three, four, or more. In the illustrative embodiment, an insulator feature 105 is disposed between the semiconductor substrate 100 and each of the source-drain features 141, 142 to prevent current leakage therebetween, but this disclosure is not limited in this respect.

The gate electrode 120 includes a first electrode segment 120A disposed under the channel feature 111, a second electrode segment 120B disposed over the channel feature 111 and under the channel feature 112, a third electrode segment 120C disposed over the channel feature 112 and under the channel feature 113, a fourth electrode segment 120D disposed over the channel feature 113, a fifth electrode segment 120E disposed to interconnect the electrode segments 120A to 120D at one side, and a six electrode segment 120F disposed to interconnect the electrode segments 120A to 120D at another side. In this disclosure, the first, second and third electrode segments 120A, 120B and 120C may be referred to as inner electrode segments because they are formed with the stack of the channel features 111, 112, 113, and the fourth electrode segment 120D may be referred to as an outer electrode segment because it is formed over the stack of the channel features 111, 112, 113.

The semiconductor device 1 further includes a first outer spacer 108 and a second outer spacer 109 disposed respectively at opposite sides of the fourth electrode segment 120D, and, for each of the electrode segments 120A to 120C, a first inner spacer 151 and a second inner spacer 152 disposed respectively at opposite sides of the corresponding one of the electrode segments 120A to 120C, where the first inner spacer 151 is disposed between the first source-drain feature 141 and the corresponding one of the electrode segments 120A to 120C, and the second inner spacer 152 is disposed between the second source-drain feature 142 and the corresponding one of the electrode segments 120A to 120C. A first etch stop layer (ESL) segment 107A is disposed between the channel feature 113 and the first outer spacer 108, and a second ESL segment 107B is disposed between the channel feature 113 and the second outer spacer 109. A first interlayer dielectric 170 is disposed over the source-drain features 141, 142, usually with an etch stop layer (not shown) interposed between the first interlayer dielectric 170 and the source-drain features 141, 142. A first source-drain contact 161 and a second source-drain contact 162 are formed in and surrounded by the first interlayer dielectric 170, and are electrically connected to and extend into the first source-drain feature 141 and the second source-drain feature 142, respectively. Each of the first source-drain contact 161 and the second source-drain contact 162 is surrounded by a dielectric layer 165, which is disposed between the first interlayer dielectric 170 and the corresponding one of the first source-drain contact 161 and the second source-drain contact 162. Above the first interlayer dielectric 170 is an etch stop layer 175 that covers the source-drain contacts 161, 162 and the gate electrode 120. A second interlayer dielectric 180 is disposed over the etch stop layer 175.

The gate dielectric 130 includes a first dielectric segment 130A surrounding the first electrode segment 120A, a second dielectric segment 130B surrounding the second electrode segment 120B, a third dielectric segment 130C surrounding the third electrode segment 120C, and a fourth dielectric segment 130D. The first dielectric segment 130A has a portion disposed between the first electrode segment 120A and the channel feature 111. The second dielectric segment 130B has a first portion disposed between the second electrode segment 120B and the channel feature 111, and a second portion disposed between the second electrode segment 120B and the channel feature 112. The third dielectric segment 130C has a first portion disposed between the third electrode segment 120C and the channel feature 112, and a second portion disposed between the third electrode segment 120C and the channel feature 113. The fourth dielectric segment 130D has a portion disposed between the fourth electrode segment 120D and the channel feature 113.

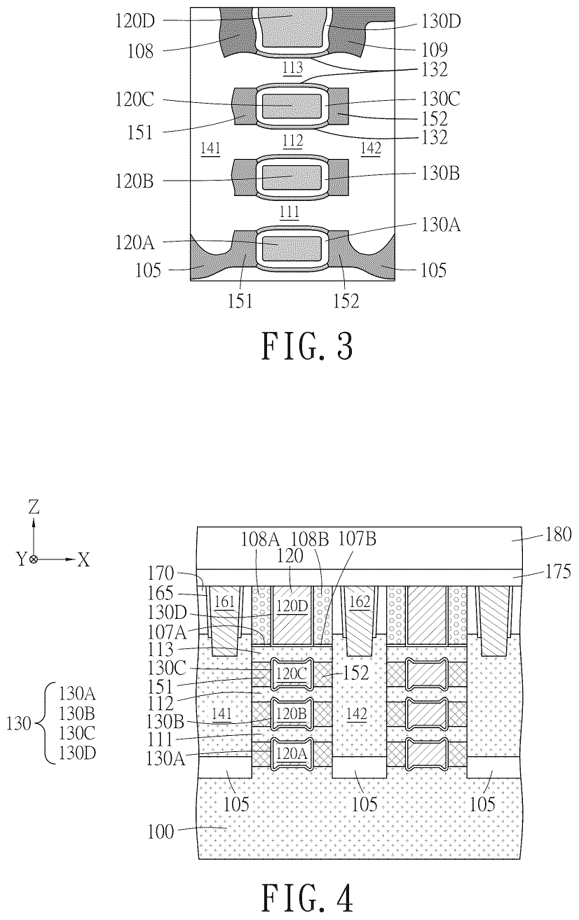

FIG. 3 illustrates an actual profile of the semiconductor device 1 that was fabricated in accordance with the first embodiment. Each of the electrode segments 120A, 120B, 120C has a substantially uniform thickness, meaning that the thickness of each of the electrode segments 120A, 120B, 120C remains nearly the same from left to right. In FIG. 3, an interfacial layer 132, which is not shown in FIG. 1, is formed between each of dielectric segments 130A, 130B, 130C, 130D and an adjacent one of the channel features 111, 112, 113 for enhancing adhesion between the dielectric segment and the channel feature.

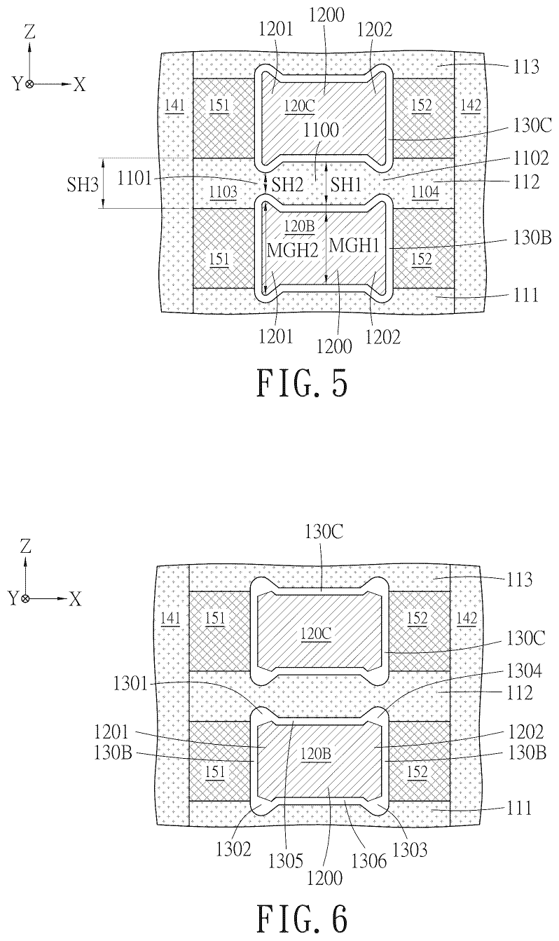

FIG. 4 illustrates an X-cut view of a semiconductor circuit structure in accordance with a second embodiment. The second embodiment is similar to the first embodiment, and differs in that each of the electrode segments 120A, 120B, 120C in the second embodiment has a dog-bone shaped profile. Further referring to FIG. 5, each of the electrode segments 120A, 120B, 120C has a central portion 1200, a first edge portion 1201 connected to the central portion 1200 at one side, and a second edge portion 1202 connected to the central portion at an opposite side. The first edge portion 1201 is disposed between the first source-drain feature 141 and the central portion 1200, and the second edge portion 1202 is disposed between the second source-drain feature 142 and the central portion 1200.

In the illustrative embodiment, each of the electrode segments 120A, 120B, 120C has a concave top surface and a concave bottom surface. For each of the electrode segments 120A, 120B, 120C, a top surface of the central portion 1200 is lower than each of a top surface of the first edge portion 1201 and a top surface of the second edge portion 1202, and a bottom surface of the central portion 1200 is higher than each of a bottom surface of the first edge portion 1201 and a bottom surface of the second edge portion 1202. The top surface of each of the first edge portion 1201 and the second edge portion 1202 extends obliquely upward from opposite ends of the central portion 1200, and a bottom surface of each of the first edge portion 1201 and the second edge portion 1202 extends obliquely downward from the opposite ends of the central portion 1200. For each of the electrode segments 120A, 120B, 120C, the thickness of each of the first edge portion 1201 and the second edge portion 1202 gradually increases from a first end that is connected to the central portion 1200 toward a second end that is opposite to the first end, and the central portion 1200 is thinner than each of the first edge portion 1201 and the second edge portion 1202. In other words, a central inner-gate height MGH1 of the central portion 1200 is less than an edge inner-gate height MGH2 of each of the first edge portion 1201 and the second edge portion 1202.

Each of the channel features 111, 112, 113 includes a central portion 1100, a first neck portion 1101 connected to the central portion 1100 at one side, a second neck portion 1102 connected to the central portion 1100 at an opposite side, a first edge portion 1103 connected to the first neck portion 1101 and opposite to the central portion 1100, and a second edge portion 1104 connected to the second neck portion 1102 and opposite to the central portion 1100. The central portion 1100 of each of the channel features 111, 112, 113 corresponds in position to the central portion 1200 of the adjacent one of the electrode segments 120A, 120B, 120C. The first neck portion 1101 is disposed between the central portion 1100 and the first source-drain feature 141, and corresponds in position to the first edge portion 1201 of the adjacent one of the electrode segments 120A, 120B, 120C. The second neck portion 1102 is disposed between the central portion 1100 and the second source-drain feature 142, and corresponds in position to the second edge portion 1202 of the adjacent one of the electrode segments 120A, 120B, 120C. The first edge portion 1103 is disposed between the first neck portion 1101 and the first source-drain feature 141. The second edge portion 1104 is disposed between the second neck portion 1102 and the second source-drain feature 142. In the illustrative embodiment, the central portion 1100 of the channel feature 112 is disposed between the central portions 1200 of the second electrode segment 120B and the third electrode segment 120C. The first neck portion 1101 of the channel feature 112 is disposed between the first edge portions 1201 of the second electrode segment 120B and the third electrode segment 120C. The second neck portion 1102 of the channel feature 112 is disposed between the second edge portions 1202 of the second electrode segment 120B and the third electrode segment 120C. The first edge portion 1103 of the channel feature 112 is disposed between the first inner spacers 151 that are adjacent to the second electrode segment 120B and the third electrode segment 120C, respectively. The second edge portion 1104 of the channel feature 112 is disposed between the second inner spacers 152 that are adjacent to the second electrode segment 120B and the third electrode segment 120C, respectively.

In the illustrative embodiment, a top surface of each of the channel features 111, 112 has indentations at the first neck portion 1101 and the second neck portion 1102, and a bottom surface of each of the channel features 111, 112, 113 has indentations at the first neck portion 1101 and the second neck portion 1102. For each of the channel features 111, 112, the top surface of each of the first neck portion 1101 and the second neck portion 1102 extends obliquely downward from the central portion 1101 to a turning section, and then extends obliquely upward from the turning section to the corresponding one of the first edge portion 1103 and the second edge portion 1104, with a slope between the central portion 1101 and the turning section being less than a slope between the turning section and the corresponding one of the first edge portion 1103 and the second edge portion 1104. For each of the channel features 111, 112, 113, the bottom surface of each of the first neck portion 1101 and the second neck portion 1102 extends obliquely upward from the central portion 1101 to a turning section, and then extends obliquely downward from the turning section to the corresponding one of the first edge portion 1103 and the second edge portion 1104, with a slope between the central portion 1101 and the turning section being less than a slope between the turning section and the corresponding one of the first edge portion 1103 and the second edge portion 1104. For each of the channel features 111, 112, 113, the thickness of each of the first neck portion 1101 and the second neck portion 1102 gradually decreases and then gradually increases from a first end that is connected to the central portion 1100 to a second end that is opposite to the first end. The central portion 1100 is thicker than a thinnest section of each of the first neck portion 1101 and the second neck portion 1102, and is thinner than each of the first edge portion 1103 and the second edge portion 1104. In other words, a central sheet height SH1 of the central portion 1101 is greater than a neck sheet height SH2 of the thinnest section of each of the first neck portion 1101 and the second neck portion 1102, and is smaller than an edge sheet height SH3 of each of the first edge portion 1103 and the second edge portion 1104.

In the illustrative embodiment, since the channel feature 112 has the relatively thinner neck portions 1101, 1102 and the adjacent electrode segments 120B, 120C have the correspondingly thicker edge portions 1201, 1202, the gate electrode 120 may achieve better control over conduction or non-conduction of the channel feature 112, and alleviate the short channel effect. On the other hand, the thicker central portion 1100 of the channel feature 112 ensures mobility of carriers when the channel feature 112 conducts, and the edge portions 1103, 1104, which are outside the coverage of the gate electrode 120, are even thicker to ensure its resistance to be sufficiently small. In accordance with some embodiments, a difference between the central sheet height SH1 and the neck sheet height SH2 is in a range from about 0.5 nm to about 5 nm, and correspondingly, a difference between the central inner-gate height MGH1 and the edge inner-gate height MGH2 ranges from about 0.5 nm to about 5 nm as well, thereby improving gate control while maintaining good carrier mobility. In accordance with some embodiments, a difference between the central sheet height SH1 and the edge sheet height SH3 is in a range from about 0.5 nm to about 10 nm, thereby allowing the semiconductor device 1 to maintain sufficiently low resistance in the edge portions 1103, 1104.

In accordance with some embodiments, each of the dielectric segments 130A, 130B, 130C may have a uniform thickness, as shown in FIGS. 4 and 5. In accordance with some embodiments, corner portions of each of the dielectric segments 130A, 130B, 130C may be thicker than other portions of each of the dielectric segments 130A, 130B, 130C, as shown in FIG. 6 (noting that the dielectric segment 130A is not shown in FIG. 6). Taking the second dielectric segment 130B as an example, the second dielectric segment 130B in FIG. 6 has a first corner portion 1301 disposed over the first edge portion 1201 of the second electrode segment 120B (i.e., disposed between the first edge portion 1201 and the channel feature 112), a second corner portion 1302 disposed under the first edge portion 1201 of the second electrode segment 120B (i.e., disposed between the first edge portion 1201 and the channel feature 111), a third corner portion 1303 disposed under the second edge portion 1202 of the second electrode segment 120B (i.e., disposed between the second edge portion 1202 and the channel feature 111), a fourth corner portion 1304 disposed over the second edge portion 1202 of the second electrode segment 120B (i.e., disposed between the second edge portion 1202 and the channel feature 112), an upper central portion 1305 disposed over the central portion 1200 of the second electrode segment 120B (i.e., disposed between the central portion 1200 and the channel feature 112) and interconnecting the first corner portion 1301 and the fourth corner portion 1304, and a lower central portion 1306 disposed under the central portion 1200 of the second electrode segment 120B (i.e., disposed between the central portion 1200 and the channel feature 111) and interconnecting the second corner portion 1302 and the third corner portion 1303, where each of the corner portions 1301, 1304 is thicker than the upper central portion 1305, and each of the corner portions 1302, 1303 is thicker than the lower central portion 1306.

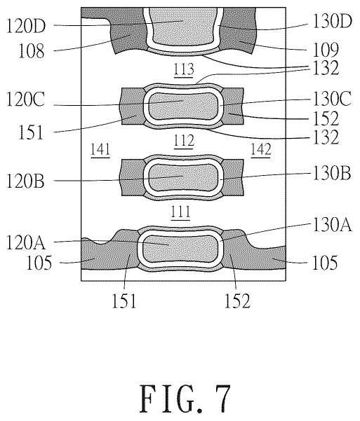

FIG. 7 illustrates an actual profile of the semiconductor device 1 that was fabricated in accordance with the second embodiment. Each of the electrode segments 120A, 120B, 120C has a dog-bone shaped profile, meaning that each of the electrode segments 120A, 120B, 120C has a central portion thinner than its edge portions. The top surface of each of the channel features 111, 112 has a W-shaped profile at an interface with an adjacent one of the electrode segments 120B, 120C, and the bottom surface of each of the channel features 111, 112, 113 has an M-shaped profile at an interface with an adjacent one of the electrode segments 120A, 120B, 120C.

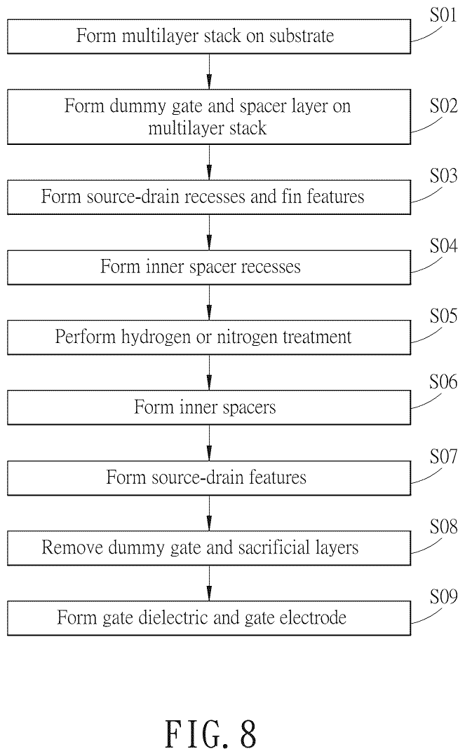

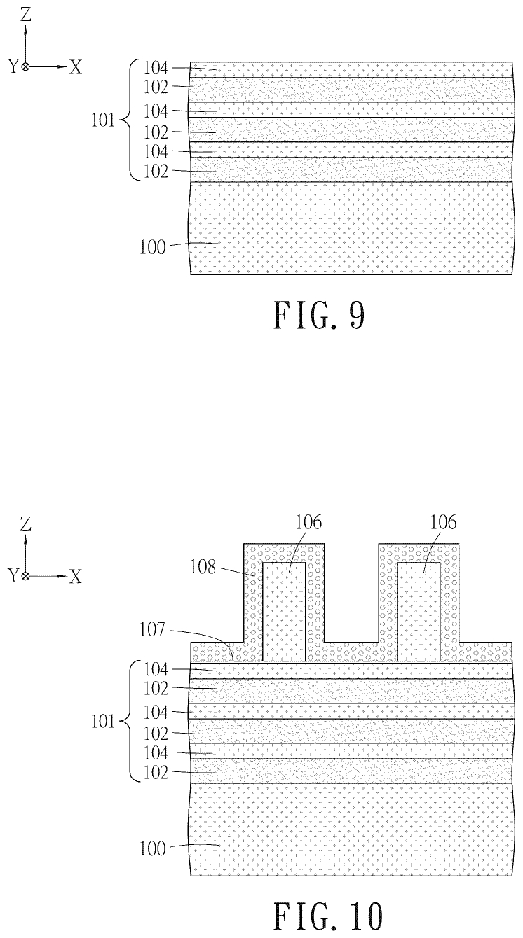

FIG. 8 is a flow chart cooperating with FIGS. 9 to 17 to illustrate a method for fabricating a semiconductor device in accordance with the second embodiment.

Referring to FIGS. 8 and 9, in step S01, a multilayer stack 101 is formed over the semiconductor substrate 100 using, for example epitaxy processes, other suitable processes, or any combination thereof. The multilayer stack 101 includes multiple sacrificial layers 102 and multiple semiconductor layers 104 that are alternately stacked together; the sacrificial layers 102 are different from the semiconductor layers 104 in terms of materials. In the illustrative embodiment, the sacrificial layers 102 are made of SiGe, and the semiconductor layers 104 are made of silicon, but this disclosure is not limited in this respect. In other embodiments, the sacrificial layers 102 and the semiconductor layers 104 may include other suitable materials, such as a compound semiconductor material (e.g., silicon carbide, gallium arsenide, gallium phosphide, indium phosphide, indium arsenide, indium antimonide, and/or other suitable materials), an alloy semiconductor material (e.g., GaAsP, AlInAs, AlGaAs, InGaAs, GaInP, GaInAsP), other suitable materials, or any combination thereof.

Referring to FIGS. 8 and 10, in step S02, an etch stop layer 107 is deposited over the multilayer stack 101, dummy gate features 106 are formed over the etch stop layer 107, and an outer spacer layer 108 is conformally deposited over the etch stop layer 107 and the dummy gate features 106. In accordance with some embodiments, the etch stop layer 107 may include, for example, SiO₂, SiC, SiN, SiCN, SiOC, SiON, SiCON, other suitable materials that have etching selectivity over the dummy gate features 106, or any combination thereof. In accordance with some embodiments, the dummy gate features 106 may include, for example, polysilicon, other suitable materials, or any combination thereof. In accordance with some embodiments, the outer spacer layer 108 may include, for example, SiO₂, SiC, SiN, SiCN, SiOC, SiON, SiCON, other suitable materials, or any combination thereof.

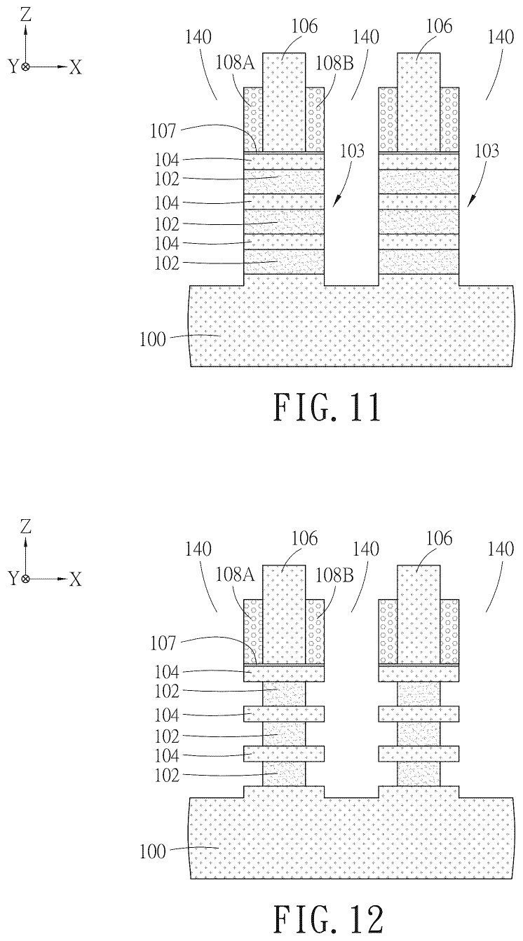

Referring to FIGS. 8 and 11, in step S03, the outer spacer layer 108 (see FIG. 10), the etch stop layer 107 and the multilayer stack 101 are partially etched to form a plurality of fin features 103 on the semiconductor substrate 100, and a plurality of source-drain recesses 140 between the fin features 103. Each of the fin features 103 is provided with a respective dummy gate feature 106, a first outer spacer 108A and a second outer spacer 108B disposed thereon, where the dummy gate feature 106 is disposed between the first outer spacer 108A and the second outer spacer 108B.

Referring to FIGS. 8 and 12, in step S04, the sacrificial layers 102 are partially etched to form recessed sacrificial layers (also denoted by the reference numerals 102). The semiconductor layers 104 and the recessed sacrificial layers 102 cooperatively form a plurality of inner spacer recesses among the semiconductor layers 104 for subsequent formation of inner spacers.

In step S05, a hydrogen treatment and/or a nitrogen treatment is performed on side surfaces of the recessed sacrificial layers 102 through the inner spacer recesses. In accordance with some embodiments, the treatment may involve introducing H₂ gas, N₂ gas, and/or NH₃ gas and applying high voltage, thereby generating hydrogen radicals and/or nitrogen radicals that react with the side surfaces of the recessed sacrificial layers 102 to enhance diffusion of germanium components from the side surfaces of the recessed sacrificial layers 102 into adjacent one(s) of the semiconductor layers 104. In accordance with some embodiments, the treatment may involve applying H₂ plasma treatment, N₂ plasma treatment, and/or NH₃ plasma treatment to generate hydrogen radicals and/or nitrogen radicals. In accordance with some embodiments, other processes that are capable of generating hydrogen radicals and/or nitrogen radicals may be utilized to perform the hydrogen/nitrogen treatment.

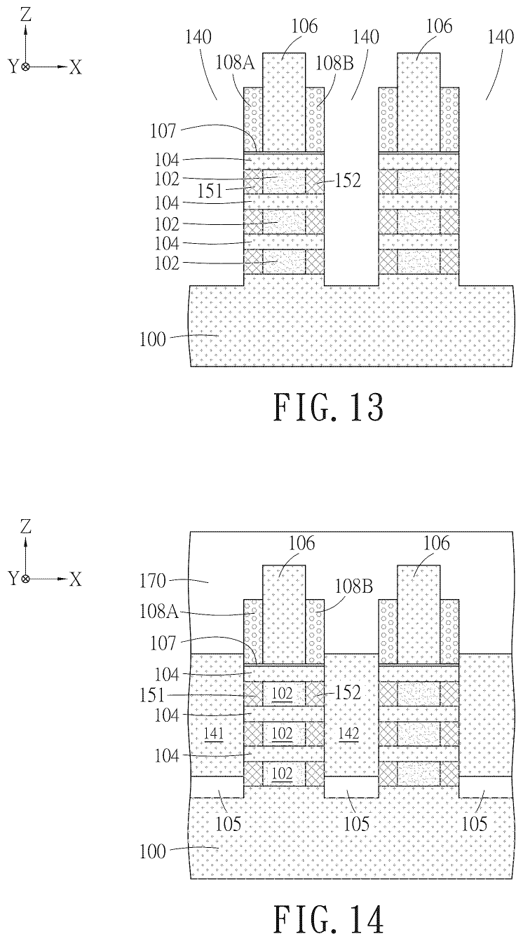

Referring to FIGS. 8 and 13, in step S06, one or more dielectric materials are deposited and partially etched to fill up the inner spacer recesses to form inner spacers 151, 152 beside the recessed sacrificial layers 102. The inner spacers 151, 152 may include, for example, SiO₂, SiC, SiN, SiCN, SiOC, SiON, SiCON, other suitable materials, or any combination thereof. In accordance with some embodiments, the process of forming the inner spacers may involve use of H₂ gas, N₂ gas, and/or NH₃ gas and induce generation of hydrogen radicals and/or nitrogen radicals. In this scenario, step S05 may be integrated into step S06, namely, the hydrogen treatment and/or the nitrogen treatment is performed during the process of forming the inner spacers 151, 152.

Referring to FIGS. 8 and 14, in step S07, the insulator features 105 and the source-drain features 141, 142 are formed in the source-drain recesses 140 (see FIG. 13), and a first interlayer dielectric 170 is formed over the source-drain features 141, 142, the outer spacers 108A, 108B and the dummy gate features 106, where the source-drain features 141, 142 are formed to be connected to opposite ends of the semiconductor layers 104, respectively. In accordance with some embodiments, the insulator features 105 may include, for example, SiO₂, SiN, SiCN, SiCON, SiCO, AlO, HfO, a high-k material, other suitable materials, or any combination thereof. In accordance with some embodiments, the source-drain features 141, 142 may include, for example, Si, SiGe, SiC, other suitable materials, or any combination thereof, and may be formed using, for example, epitaxy processes, other suitable processes, or any combination thereof. In accordance with some embodiments, the first interlayer dielectric 170 may include, for example, SiO₂, SiN, SiC, a low-k material, other suitable materials, or any combination thereof. In accordance with some embodiments, a contact etch stop layer (not shown) may be formed between the first interlayer dielectric 170 and each of the source-drain features 141, 142 in order to prevent oxidation of the source-drain features 141, 142, and include, for example, SiN, SiC, a low-k material, other suitable materials, or any combination thereof.

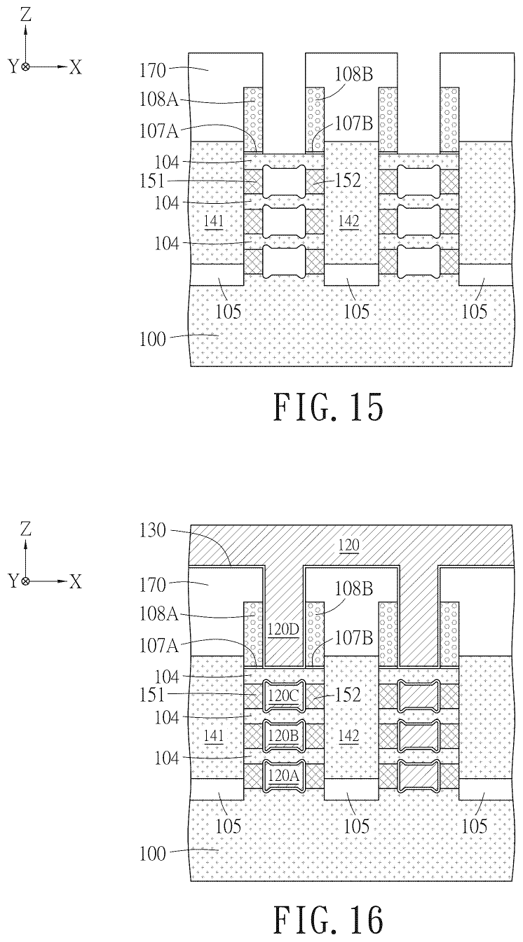

Referring to FIGS. 8 and 15, in step S08, the dummy gate features 106 and the recessed sacrificial layers 102 (see FIG. 14) are removed. Due to the hydrogen treatment and/or the nitrogen treatment performed in step S05, the germanium components in the side surfaces of the recessed sacrificial layers 102 may diffuse upward and/or downward into portions of the adjacent semiconductor layers 104, so those portions of the semiconductor layers 104 may be removed as well during the removal of the recessed sacrificial layers 102. As a result, the semiconductor layers 104 are formed to have indentations at positions corresponding to the side surfaces of the recessed sacrificial layers 102, and the resultant cavities between the partially removed semiconductor layers 104 have a dog-bone shaped profile as shown in FIG. 15. In step S08, a segment of the etch stop layer 107 (see FIG. 14) that is revealed after removal of the dummy gate features 106 is also removed, thereby leaving a first ESL segment 107A disposed between the first outer spacer 108A and the upmost one of the semiconductor layers 104, and a second ESL segment 107B disposed between the second outer spacer 108B and the upmost one of the semiconductor layers 104.

Referring to FIGS. 8 and 16, in step S09, the conformal gate dielectric 130 and the gate electrode 120 are deposited to fill the cavities among the semiconductor layers 104 and the recess between the first outer spacer 108A and the second outer spacer 108B (i.e., the space that was originally occupied by the dummy gate features 106, as shown in FIG. 14). Accordingly, the resultant electrode segments 120A, 120B, 120C fit the shapes of the cavities, and thus have a dog-bone shaped profile. In accordance with some embodiments, the gate dielectric 130 may include, for example, SiO₂, SiN, SiCN, SiCON, SiCO, AlO, HfO, high-k materials, other suitable materials, or any combination thereof. A profile of each of the dielectric segments 130A, 130B, 130C may be formed as shown in FIG. 5 or FIG. 7, depending on process control. In accordance with some embodiments, the gate electrode 120 may include, for example, Cu, Ti, TiN, W, Al, Co, Ru, other suitable materials, or any combination thereof. Through steps S08 and S09, the sacrificial layers 102 (see FIG. 14) are replaced with a dielectric film and a metal material to form the gate dielectric 130 and the gate electrode 120.

Then, the dielectric layer 165 and the source-drain contacts 161, 162 are formed in the first interlayer dielectric 170, followed by depositing the etch stop layer 175 and the second interlayer dielectric 180, so the structure as shown in FIG. 4 is formed, where the semiconductor layers 104 (see FIG. 16) serve as the channel features 111, 112, 113, respectively. In accordance with some embodiments, the dielectric layer 165 may include, for example, SiN, SiO2, SiON, SiCON, a low-k material, other suitable materials, or any combination thereof. The dielectric layer 165 may prevent current leakage or voltage breakdown between the gate electrode 120 and the source-drain contacts 161, 162 if there is poor overlay of the source-drain contacts 161, 162. In accordance with some embodiments, the source-drain contacts 161, 162 may include, for example, Co, W, Ru, Cu, Al, Mo, Ti, Ni, Au, Pt, Pd, other suitable conductive materials, or any combination thereof.

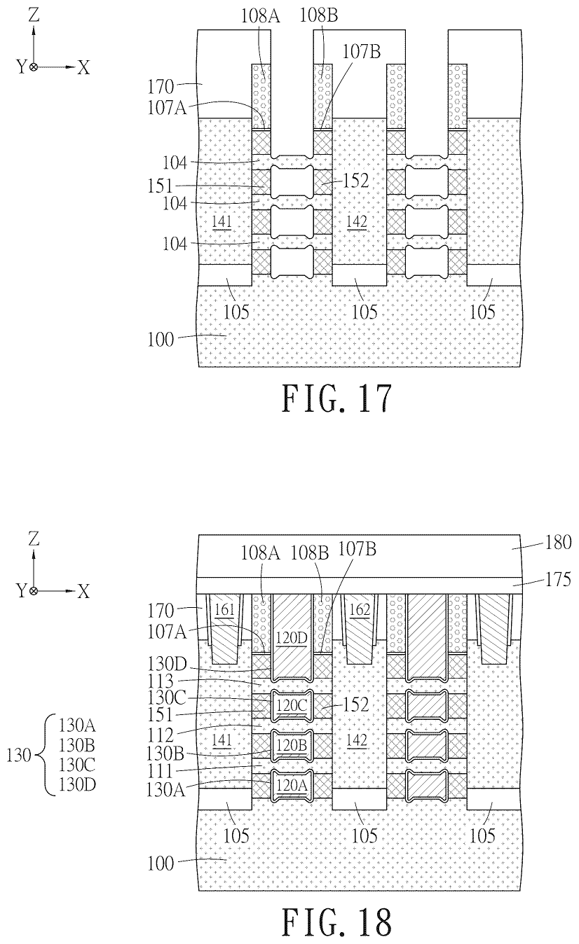

Referring to FIGS. 8 and 9 again, in the aforesaid embodiment, the uppermost layer of the multilayer stack 101 formed in step S01 is a semiconductor layer 104. In accordance with a first variation of the second embodiment, the uppermost layer of the multilayer stack 101 may be a sacrificial layer 102. In this scenario, a structure as illustrated in FIG. 17 may be formed through steps S01 to S08. Just as other sacrificial layers 102 in FIG. 12, the upmost sacrificial layer in the first variation would be etched to be recessed in step S04, and its side surfaces would undergo the hydrogen treatment and/or nitrogen treatment in step S05, so the germanium components in the side surfaces of the recessed upmost sacrificial layer would diffuse into the underlying semiconductor layer 104. As a result, portions of that semiconductor layer 104 that correspond in position to the side surfaces of the recessed upmost sacrificial layer would be removed in step S08, thereby forming indentations in a top surface of that semiconductor layer 104. FIG. 18 illustrates a semiconductor circuit structure that is formed in accordance with the first variation of the second embodiment, where the fourth electrode segment 120D has two corner portions that extend downward into the channel feature 113, making the channel feature 113 have a similar profile to the channel features 111, 112. This configuration may further enhance gate control over the channel feature 113.

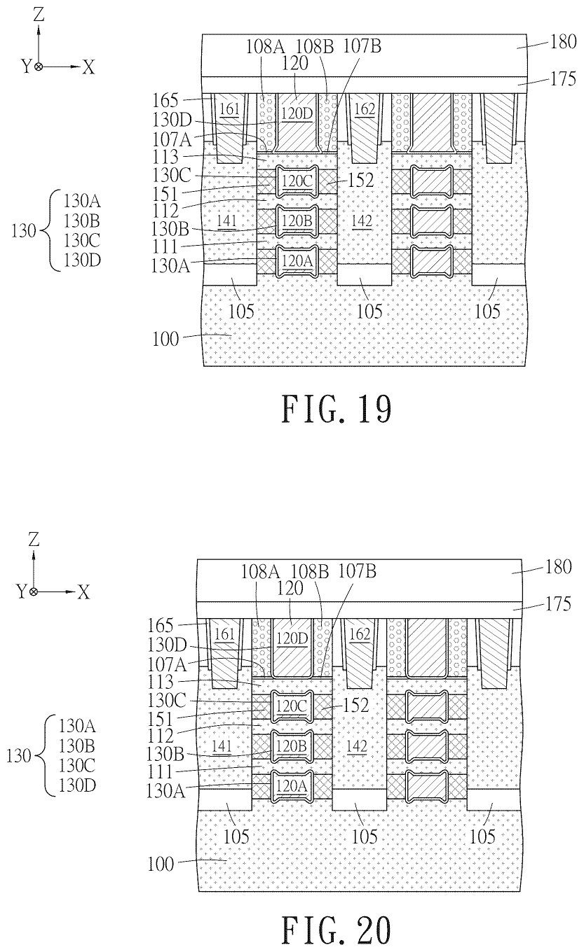

FIG. 19 illustrates a semiconductor circuit structure in accordance with a second variation of the second embodiment. The structure of the second variation is similar to the structure shown in FIG. 4, and differs in that the fourth electrode segment 120D in the second variation includes a body portion having substantially the same width as the first to third electrode segments 120A, 120B, 120C, and two corner portions that extend outward and horizontally from a bottom of the body portion and over the channel feature 113. As a result, each of the extending corner portions are disposed between the channel feature 113 and a respective one of the outer spacers 108A, 108B. In order to form such configuration, a length of time taken for etching the revealed segment of the etch stop layer 107 (see FIG. 14) in step S08 (see FIG. 8) may be purposefully extended, so that the first ESL segment 107A and the second ESL segment 107B are partially removed as well through the recess between the first outer spacer 108A and the second outer spacer 108B, thereby forming gaps between the outer spacers 108A, 108B and the upmost one of the semiconductor layers 104. Then, the gate dielectric 130 and the gate electrode 120 would be deposited in the gaps in step S09 (see FIG. 8), forming the corner portions of the fourth electrode segment 120D. This configuration causes the fourth electrode segment 120D to have a larger control area over the channel feature 113, thereby alleviating the short channel effect that may lead to current leakage.

FIG. 20 illustrates a semiconductor circuit structure in accordance with a third variation of the second embodiment. The structure of the third variation is similar to the structure as shown in FIG. 4, and differs in that the fourth electrode segment 120D in the third variation has a U-shaped contour. In detail, the fourth electrode segment 120D of the third variation includes a body portion having substantially the same width as the first to third electrode segments 120A, 120B, 120C, and a bottom portion having a gradually reduced width that forms rounded bottom corners. In order to form such configuration, the length of time taken for etching the revealed segment of the etch stop layer 107 (see FIG. 14) in step S08 (see FIG. 8) may be purposefully shortened, so that the revealed segment of the etch stop layer 107 is not completely removed, leaving its partially-etched edge portions still present. Then, the illustrated profile of the fourth electrode segment 120D is formed after the gate dielectric 130 and the gate electrode 120 are deposited in step S09 (see FIG. 8). This configuration may reduce the risk of over-etching the etch stop layer 107, which could cause the fourth electrode segment 120D to be too close to the source-drain features 141, 142, thereby achieving a better production yield.

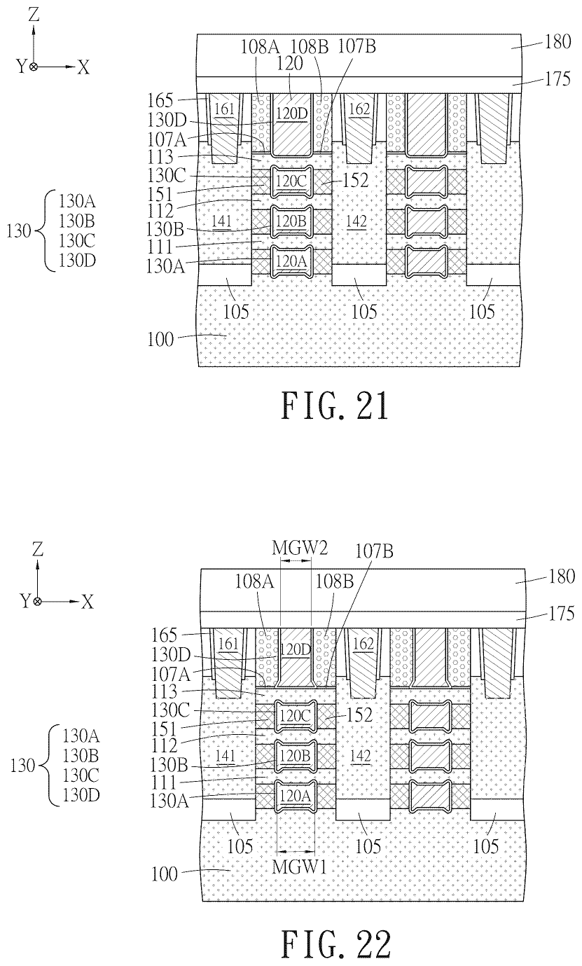

FIG. 21 illustrates a semiconductor circuit structure in accordance with a fourth variation of the second embodiment. The fourth variation is similar to the third variation, and differs in that the channel feature 113 of the fourth variation is formed with a recess in its top surface, so a part of the fourth dielectric segment 130D is formed in that recess, and a central portion of a bottom of the fourth electrode segment 120D is disposed in the channel feature 113. In order to form such configuration, the upmost one of the semiconductor layers 104 (see FIG. 15) may be slightly etched after removal of the dummy gate feature 106 and the part of the etch stop layer 107 under the dummy gate feature 106 (see FIG. 14) and before formation of the gate dielectric 130 and the gate electrode 120, so as to make the central portion of the channel feature 113 thinner than the central portions of the channel features 111, 112. As a result, unlike the channel feature 111 or 112 whose top surface and the bottom surface have horizontally-symmetric profiles, the profiles of the top surface and the bottom surface of the channel feature 113 are horizontally asymmetric. The thinner channel feature 113 may enhance gate control and improve the short channel effect.

FIG. 22 illustrates a semiconductor circuit structure in accordance with a fifth variation of the second embodiment. The fifth variation is similar to the second variation (see FIG. 19), and differs in that, in the fifth variation, the body portion of the fourth electrode segment 120D is narrower than the first to third electrode segments 120A, 120B, 120C (i.e., MGW2<MGW1), while a bottom width of the fourth electrode segment 120D, which refers to a sum of the widths of the body portion and the two corner portions, is not smaller than the width of the first to third electrode segments 120A, 120B, 120C. In the illustrative embodiment, the bottom width of the fourth electrode segment 120D is substantially equal to the width of the first to third electrode segments 120A, 120B, 120C. The narrower body portion of the fourth electrode segment 120D cooperates with wider outer spacers 108A, 108B to reduce parasitic capacitance between the fourth electrode segment 120D and the source-drain contacts 161, 162, while the extending corner portions ensures sufficient gate control over the channel feature 113, thereby attaining better device performance.

The aforesaid embodiments and variations may be applied to either n-type transistors or p-type transistors. In accordance with some embodiments, the p-type transistors may have thicker channel features than the n-type transistors for reducing resistance of the p-type transistors. In accordance with some embodiments, an average thickness of the channel features of the p-type transistors may be greater than that of the n-type transistors by about 0.3 nm to about 2 nm. In accordance with some embodiments, an average width of the inner electrode segments of the p-type transistors may be greater than that of the n-type transistors by about 0.5 nm to about 5 nm, and correspondingly, an average width of the inner spacers of the p-type transistors may be smaller than that of the n-type transistors by about 0.3 nm to about 3 nm, thereby enlarging junction overlaps between the channel features and the inner electrode segments for further reduction of the resistance of the p-type transistors.

In accordance with some embodiments, a method for fabricating a semiconductor device is provided. In one step, a fin feature is provided over a semiconductor substrate, and a dummy gate feature is disposed over the fin feature. The fin feature includes a plurality of sacrificial layers and a plurality of semiconductor layers that are alternately stacked together. In one step, the sacrificial layers are etched to form recessed sacrificial layers. In one step, hydrogen treatment or nitrogen treatment is performed on side surfaces of the recessed sacrificial layers. In one step, inner spacers are formed on the recessed sacrificial layers. In one step, a first source-drain feature and a second source-drain feature are formed respectively at a first end and a second end of the semiconductor layers of the fin feature. In one step, the dummy gate feature is removed. In one step, the recessed sacrificial layers are etched. During the etching of the recessed sacrificial layers, the semiconductor layers of the fin feature are formed to have indentations at positions corresponding to the side surfaces of the recessed sacrificial layers. In one step, a gate dielectric and a gate electrode are formed on the semiconductor layers of the fin feature.

In accordance with some embodiments, the semiconductor layers serve as channel features of the semiconductor device, and the gate electrode has a first electrode segment disposed under one of the channel features, a second electrode segment disposed over the one of the channel features, and a connecting electrode segment interconnecting the first electrode segment and the second electrode segment. The first electrode segment has a central portion, a first edge portion disposed between the central portion and the first source-drain feature, and a second edge portion disposed between the central portion and the second source-drain feature. The central portion of the first electrode segment is thinner than each of the first edge portion and the second edge portion of the first electrode segment.

In accordance with some embodiments, the first electrode segment has a dog-bone shaped profile.

In accordance with some embodiments, each of the first edge portion and the second edge portion of the first electrode has a first end that is connected to the central portion, and a second end opposite to the first end, and has a thickness that gradually increases from the first end to the second end.

In accordance with some embodiments, a top surface of the central portion of the first electrode segment is lower than each of a top surface of the first edge portion and a top surface of the second edge portion of the first electrode segment. A bottom surface of the central portion of the first electrode segment is higher than each of a bottom surface of the first edge portion and a bottom surface of the second edge portion of the first electrode segment.

In accordance with some embodiments, the one of the channel features includes a central portion, a first neck portion disposed between the central portion and the first source-drain feature, a first edge portion disposed between the first neck portion and the first source-drain feature, a second neck portion disposed between the central portion and the second source-drain feature, and a second edge portion disposed between the second neck portion and the second source-drain feature. The first neck portion is thinner than both of the central portion and the first edge portion. The second neck portion is thinner than both of the central portion and the second edge portion.

In accordance with some embodiments, for the one of the channel features, the central portion is thinner than each of the first edge portion and the second edge portion.

In accordance with some embodiments, the central portion of the one of the channel features corresponds in position to the central portion of the first electrode segment of the gate electrode, the first neck portion of the one of the channel features corresponds in position to the first edge portion of the first electrode segment of the gate electrode, and the second neck portion of the one of the channel features corresponds in position to the second edge portion of the first electrode segment of the gate electrode.

In accordance with some embodiments, the fin feature and the dummy gate feature are provided with an etch stop layer being formed over the fin feature, with a first outer spacer and a second outer spacer being formed respectively over a first segment and a second segment of the etch stop layer and respectively at two sides of the dummy gate feature, and with the dummy gate feature being formed over a third segment of the etch stop layer. The removal of the dummy gate feature forms a recess between the first outer spacer and the second outer spacer, and the third segment of the etch stop layer is revealed from the recess. In one step, before forming a gate dielectric and a gate electrode, the etch stop layer is etched through the recess in such a way that the third segment of the etch stop layer is removed, and that each of the first segment and the second segment of the etch stop layer are partially removed.

In accordance with some embodiments, the gate electrode has a first extending portion disposed between the first outer spacer and the fin feature, and a second extending portion disposed between the second outer spacer and the fin feature.

In accordance with some embodiments, the gate electrode has an outer electrode segment formed between the first outer spacer and the second outer spacer, and the first extending portion and the second extending portion extend outward from the outer electrode segment. The outer electrode segment is narrower than the first electrode segment.

In accordance with some embodiments, a semiconductor device is provided to include a channel feature disposed over a semiconductor substrate, a gate electrode surrounding the channel feature, a gate dielectric disposed between the gate electrode and the channel feature, a first source-drain feature connected to a first end of the channel feature, and a second source-drain feature connected to a second end of the channel feature. The gate electrode has a first electrode segment disposed under the channel feature, a second electrode segment disposed over the channel feature, and a connecting electrode segment interconnecting the first electrode segment and the second electrode segment. The first electrode segment has a central portion, a first edge portion disposed between the central portion and the first source-drain feature, and a second edge portion disposed between the central portion and the second source-drain feature. The central portion of the first electrode segment is thinner than each of the first edge portion and the second edge portion of the first electrode segment.

In accordance with some embodiments, the second electrode segment has a corner portion that extends into the channel feature.

In accordance with some embodiments, the second electrode segment has a body portion, and a corner portion that extends outward from a bottom of the body portion.

In accordance with some embodiments, the second electrode segment has a rounded bottom corner.

In accordance with some embodiments, a central portion of a bottom of the second electrode segment is disposed in the channel feature.

In accordance with some embodiments, the gate dielectric has a first portion disposed between the central portion of the first electrode segment and the channel feature, and a second portion disposed between the first edge portion of the first electrode segment and the channel feature. The second portion of the gate dielectric is thicker than the first portion of the gate dielectric.

In accordance with some embodiments, a method for fabricating a semiconductor device is provided. In one step, a fin feature is provided over a semiconductor substrate, and a dummy gate feature is disposed over the fin feature. The fin feature includes a plurality of sacrificial layers and a plurality of semiconductor layers that are alternately stacked together. In one step, the sacrificial layers are etched to form inner spacer recesses. In one step, hydrogen treatment or nitrogen treatment is performed on the sacrificial layers through the inner spacer recesses. In one step, inner spacers are formed in the inner spacer recesses. In one step, a first source-drain feature and a second source-drain feature are formed respectively at a first end and a second end of the semiconductor layers of the fin feature. In one step, the sacrificial layers are replaced with a dielectric film and a metal material.

In accordance with some embodiments, the performing of the hydrogen treatment or the nitrogen treatment includes plasma treatment.

In accordance with some embodiments, the hydrogen treatment or the nitrogen treatment is performed during the forming of the inner spacers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a semiconductor device, comprising:
providing a fin feature over a semiconductor substrate, and a dummy gate feature disposed over the fin feature, wherein the fin feature includes a plurality of sacrificial layers and a plurality of semiconductor layers that are alternately stacked together;
etching the sacrificial layers to form recessed sacrificial layers;
performing hydrogen treatment or nitrogen treatment on side surfaces of the recessed sacrificial layers;
forming inner spacers on the recessed sacrificial layers;
forming a first source-drain feature and a second source-drain feature respectively at a first end and a second end of the semiconductor layers of the fin feature;
removing the dummy gate feature;
etching the recessed sacrificial layers, during which the semiconductor layers of the fin feature are formed to have indentations at positions corresponding to the side surfaces of the recessed sacrificial layers; and
forming a gate dielectric and a gate electrode on the semiconductor layers of the fin feature.

2. The method according to claim 1, wherein the semiconductor layers serve as channel features of the semiconductor device, and the gate electrode has a first electrode segment disposed under one of the channel features, a second electrode segment disposed over the one of the channel features, and a connecting electrode segment interconnecting the first electrode segment and the second electrode segment;
wherein the first electrode segment has a central portion, a first edge portion disposed between the central portion and the first source-drain feature, and a second edge portion disposed between the central portion and the second source-drain feature; and
wherein the central portion of the first electrode segment is thinner than one of the first edge portion and the second edge portion of the first electrode segment.

3. The method according to claim 2, wherein the first electrode segment has a dog-bone shaped profile.

4. The method according to claim 2, wherein each of the first edge portion and the second edge portion of the first electrode has a first end that is connected to the central portion, and a second end opposite to the first end, and has a thickness that gradually increases from the first end to the second end.

5. The method according to claim 2, wherein a top surface of the central portion of the first electrode segment is lower than each of a top surface of the first edge portion and a top surface of the second edge portion of the first electrode segment; and
wherein a bottom surface of the central portion of the first electrode segment is higher than each of a bottom surface of the first edge portion and a bottom surface of the second edge portion of the first electrode segment.

6. The method according to claim 2, wherein the one of the channel features includes a central portion, a first neck portion disposed between the central portion and the first source-drain feature, a first edge portion disposed between the first neck portion and the first source-drain feature, a second neck portion disposed between the central portion and the second source-drain feature, and a second edge portion disposed between the second neck portion and the second source-drain feature;
wherein the first neck portion is thinner than both of the central portion and the first edge portion; and
wherein the second neck portion is thinner than both of the central portion and the second edge portion.

7. The method according to claim 6, wherein, for the one of the channel features, the central portion is thinner than each of the first edge portion and the second edge portion.

8. The method according to claim 6, wherein the central portion of the one of the channel features corresponds in position to the central portion of the first electrode segment of the gate electrode, the first neck portion of the one of the channel features corresponds in position to the first edge portion of the first electrode segment of the gate electrode, and the second neck portion of the one of the channel features corresponds in position to the second edge portion of the first electrode segment of the gate electrode.

9. The method according to claim 1, wherein the fin feature and the dummy gate feature are provided with an etch stop layer being formed over the fin feature, with a first outer spacer and a second outer spacer being formed respectively over a first segment and a second segment of the etch stop layer and respectively at two sides of the dummy gate feature, and with the dummy gate feature being formed over a third segment of the etch stop layer;
wherein the removal of the dummy gate feature forms a recess between the first outer spacer and the second outer spacer, and the third segment of the etch stop layer is revealed from the recess;
wherein said method further comprises, before forming a gate dielectric and a gate electrode:
etching the etch stop layer through the recess in such a way that the third segment of the etch stop layer is removed, and that each of the first segment and the second segment of the etch stop layer are partially removed.

10. The method according to claim 9, wherein the gate electrode has a first extending portion disposed between the first outer spacer and the fin feature, and a second extending portion disposed between the second outer spacer and the fin feature.

11. The method according to claim 10, wherein the gate electrode has an outer electrode segment formed between the first outer spacer and the second outer spacer, and the first extending portion and the second extending portion extend outward from the outer electrode segment;
wherein the outer electrode segment is narrower than the first electrode segment.

12. A semiconductor device, comprising:
a channel feature disposed over a semiconductor substrate;
a gate electrode surrounding the channel feature;
a gate dielectric disposed between the gate electrode and the channel feature;
a first source-drain feature connected to a first end of the channel feature;
and a second source-drain feature connected to a second end of the channel feature;
wherein the gate electrode has a first electrode segment disposed under the channel feature, a second electrode segment disposed over the channel feature, and a connecting electrode segment interconnecting the first electrode segment and the second electrode segment;
wherein the first electrode segment has a central portion, a first edge portion disposed between the central portion and the first source-drain feature, and a second edge portion disposed between the central portion and the second source-drain feature; and
wherein the central portion of the first electrode segment is thinner than one of the first edge portion and the second edge portion of the first electrode segment.

13. The semiconductor device according to claim 12, wherein the second electrode segment has a corner portion that extends into the channel feature.

14. The semiconductor device according to claim 12, wherein the second electrode segment has a body portion, and a corner portion that extends outward from a bottom of the body portion.

15. The semiconductor device according to claim 12, wherein the second electrode segment has a rounded bottom corner.

16. The semiconductor device according to claim 12, wherein a central portion of a bottom of the second electrode segment is disposed in the channel feature.

17. The semiconductor device according to claim 12, wherein the gate dielectric has a first portion disposed between the central portion of the first electrode segment and the channel feature, and a second portion disposed between the first edge portion of the first electrode segment and the channel feature; and
wherein the second portion of the gate dielectric is thicker than the first portion of the gate dielectric.

18. A method for fabricating a semiconductor device, comprising:
providing a fin feature over a semiconductor substrate, and a dummy gate feature disposed over the fin feature, wherein the fin feature includes a plurality of sacrificial layers and a plurality of semiconductor layers that are alternately stacked together;
etching the sacrificial layers to form inner spacer recesses;
performing hydrogen treatment or nitrogen treatment on the sacrificial layers through the inner spacer recesses;
forming inner spacers in the inner spacer recesses;
forming a first source-drain feature and a second source-drain feature respectively at a first end and a second end of the semiconductor layers of the fin feature; and
replacing the sacrificial layers with a dielectric film and a metal material.

19. The method according to claim 18, wherein the performing of the hydrogen treatment or the nitrogen treatment includes plasma treatment.

20. The method according to claim 18, wherein the hydrogen treatment or the nitrogen treatment is performed during the forming of the inner spacers.
